(19) United States
(12) Patent Application Publication
(10) Pub. No.: US 2011/0140130 A1
(43) Pub. Date: Jun. 16, 2011

(54) Method for Forming a Thin-film Structure of a Light-Emitting Device via Nanoimprint

(75) Inventors: Sun-Zen Chen, Taoyuan County (TW); Shih-Liang Ku, Taipei County (TW); Cheng-Chung Chi, Taipei (TW)

(73) Assignee: Chung-Shan Institute of Science and Technology, Armaments, Bureau, Ministry of National Defense, Taoyuan County (TW)

(21) Appl. No.: 12/957,614

(22) Filed: Dec. 1, 2010

(30) Foreign Application Priority Data
Dec. 10, 2009 (TW) 098142283

(51) Int. Cl. H01L 33/00; B29C 59/02

(52) U.S. Cl. 257/79; 264/293; 257/E33.001

(57) ABSTRACT

A method is disclosed for making a thin-film structure of a light-emitting device via nanoimprint. The method includes the steps of providing a light-emitting element, providing a film on the light-emitting element via spin coating precursor on the light-emitting element, forming a pattern on the film by nanoimprint; and curing the film. Thus, the precursor is transformed to the thin-film structure.

### BACKGROUND OF INVENTION

1. Field of Invention

The present invention relates to a method for forming a thin-film structure of a light-emitting device via nanoimprint and, more particularly, to a method for providing a light-emitting device with a thin-film structure of precursor such as a sol-gel material and spin-on glass via nanoimprint.

2. Conventional Methods

Conventionally, a method for transferring a pattern comprises a serial complex photolithography procedure, includes the steps of coating photo-resist, baking, exposure, development and etc. Furthermore, an expensive EUV stepper is demanded to achieve small line width of the pattern. It is however difficult for a conventional photolithography method to obtain a nano-scaled line width pattern, as well as the expansive EUV stepper may increase the process cost.

On the other hand, nanoimprint is proposed to transfer nanoscale patterns in an easier way. In nanoimprint, a mold, stamp or template is pressed on photo-resist so that the photo-resist is mechanically deformed for transferring a pattern. Once made, the mold can be used to form nanostructures repeatedly. Nanoimprint is therefore economic and promising.

Nanoimprint can be classified into two categories: hot embossing nanoimprint and UV-curing nanoimprint. In hot embossing nanoimprint, a mold is pressed on a polymer or resin that has been heated to a temperature higher than the glass transition temperature. The mold is removed from the polymer or resin after the polymer or resin is cooled. Thus, micro- to nanoscale patterns is replicated onto the polymer or resin. After a series of fabrication process, the patterns can be transferred onto substrate.

In UV-curing nanoimprint, a UV light source is used to expose the photo-resist via pressing a patterned transparent mold onto the photo-resist at room temperature and then induce a cross-linking reaction of the photo-resist. A series of fabrication process also demanded to transfer the patterns from the photo-resist to the substrate.

Referring to FIGS. 1 through 5, in a typical UV-curing nanoimprint process (U.S. Pat. No. 6,334,960), a mold 90 is pressed on a substrate 94 coated with a resist layer 92. A UV curable polymer precursor 96 is filled in a gap between the mold 90 and the resist layer 92. The polymer 96 is exposed to and cured by ultra violet light. Then, the mold 90 is removed from the cured polymer 96. Thus, a pattern is transferred, and can later be used as an etching mask. However, the materials of the mold 90, the resist layer 92, the substrate 94 and the polymer 96 are limited, and the mold 90 or the substrate 94 must be transparent. Moreover, the resist layer 92 and the polymer 96 might be too weak to survive the etching especially for deep etching, and the pattern might be distorted after the etching. To solve, a temporary intermediate layer between the resist layer 92 and substrate 94 is added to improve the pattern fidelity. Although it may obtain accuracy patterns for transferring patterns from layer 92 to intermediate layer and then to substrate 94, the extra steps increase the complexity and cost of the process.

Although the typical nanoimprints and step and flash photolithography can be used to form nano-scaled patterns on substrate in high throughput, the patterns is formed on the resist first and then transferred to the substrate by series procedures. They all require extra steps to ensure the fidelity of the patterns, as discussed above.

Another concerning of this invention is focusing on providing a light extraction structure of LED with an easier fabrication method without a complex photolithography process.

The refractive indexes of semiconductors used to make light-emitting diodes (“LED”s) are high. There is loss of light due to total reflection on the surface and at the interface. For example, the refractive index of GaP is 3.5, and only 19% of light is extracted because of total reflection.

LED manufacturers are working hard to reduce the cost of luminance per unit area so that the LED can be accepted in the market as the solid lighting source. Conventionally, a roughing surface texture is made on the surface of the LED or a reflecting metal mirror is added into the LED to increase the light extraction efficiency of the LED. The improvement of LED can be even bigger with the use of photonic crystal, for the photonic crystal not only enhances the light extraction but also modifies the lighting profile.

The effectiveness of the photonic crystals depends on the structures of photonic crystals, such as the pattern geometry, the size of diameter, the space between the holes etc. For example, a quasi-photonic crystal can be made to cast a specific lighting profile, such as a conic beam profile, of a LED.

However, it is difficult to transfer good fidelity periodic surface structure onto LED. The LED manufacturers are forced to make expensive light-emitting devices by sol-gel methods based on index-matching glue and beam-directing optical methods.

The present invention is therefore intended to obviate or at least alleviate the problems encountered in conventional methods.

### SUMMARY OF INVENTION

It is the primary objective of the present invention to provide a method for forming a thin-film structure of a light-emitting device via nanoimprint.

To achieve the foregoing objective, the method includes the steps of providing a light-emitting element, providing a film on the light-emitting element via spin-coating a precursor on the light-emitting element, forming a pattern on the film by nanoimprint; and curing the film. Thus, the precursor is transformed into the demanded structure.

Other objectives, advantages and features of the present invention will be apparent from the following description referring to the attached drawings.

### BRIEF DESCRIPTION OF DRAWINGS

The present invention will be described via detailed illustration of several embodiments versus the prior art referring to the drawings wherein:

FIGS. 1 through 5 are cross-sectional views for showing a conventional method for making a mask;

FIG. 6 is a flow chart of a method for forming a thin-film structure of a light-emitting device via nanoimprint according to the first embodiment of the present invention;

FIGS. 7 through 10 are cross-sectional views for showing the method shown in FIG. 6;

FIG. 11 is a cross-sectional view of a light-emitting device according to a second embodiment of the present invention;

FIG. 12 is a cross-sectional view of a light-emitting device according to a third embodiment of the present invention; and

FIG. 13 is a chart of light-extraction rates in view of incident angles of the light-emitting device according to the present invention.

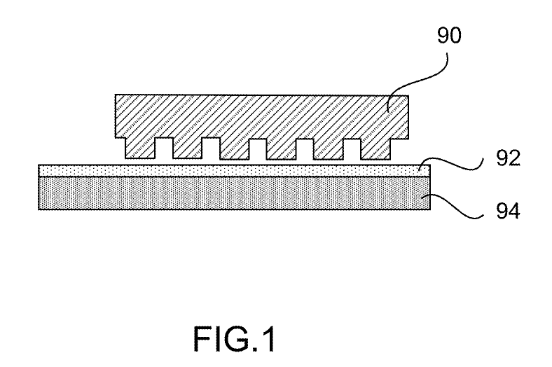

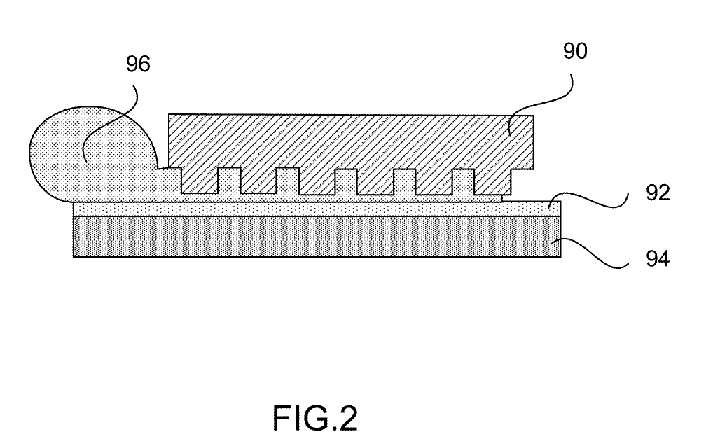

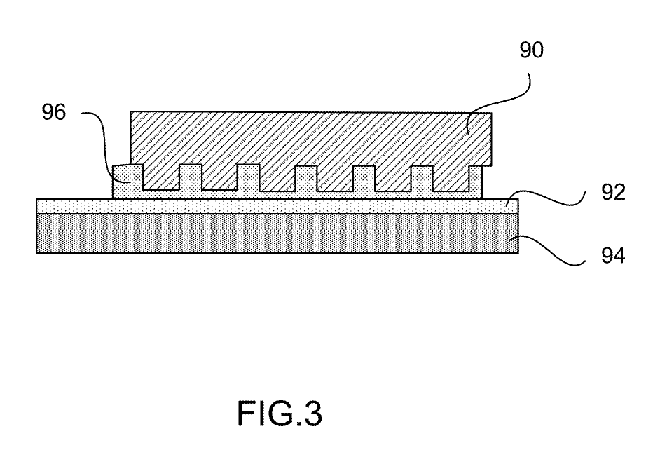

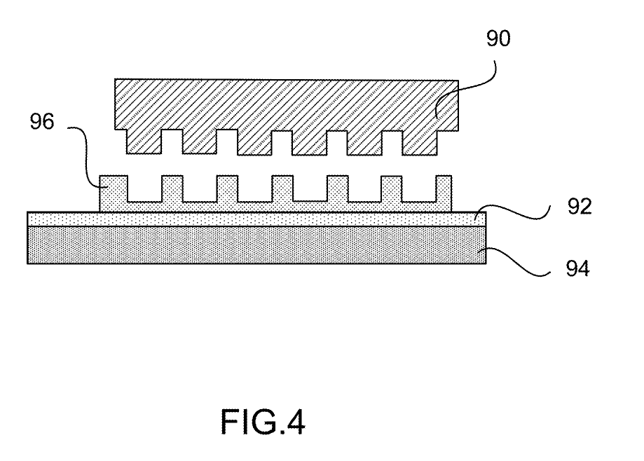

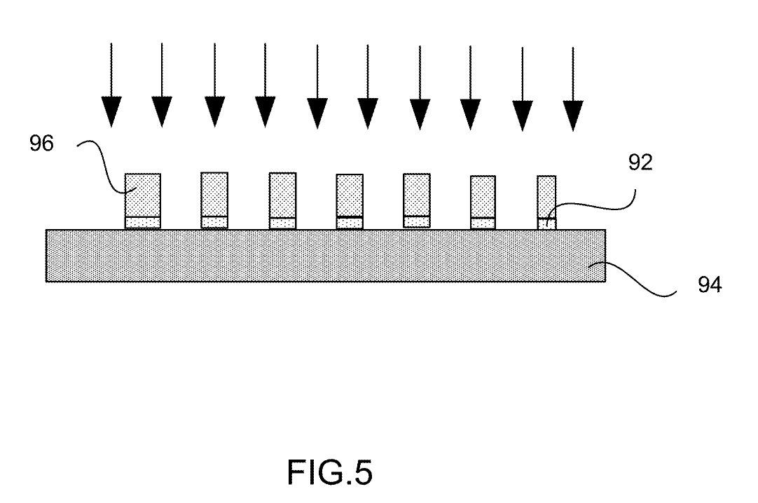

### DETAILED DESCRIPTION OF EMBODIMENTS

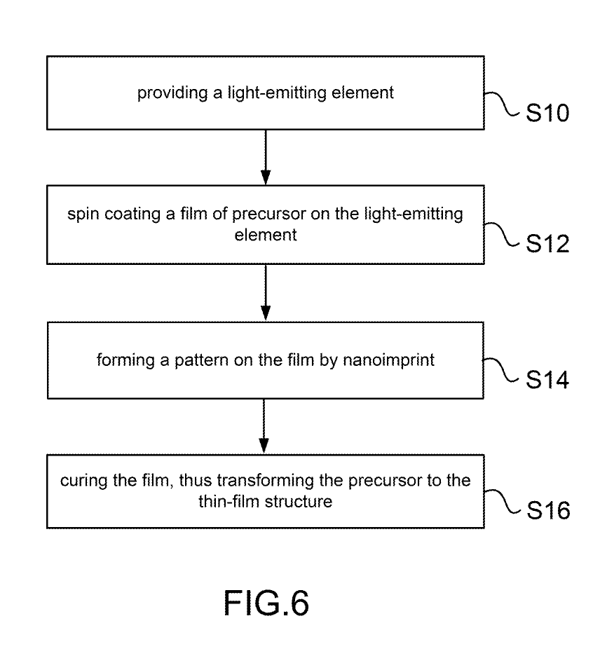

Referring to FIGS. 6 through 10, there is shown a method for forming a thin-film structure of a light-emitting device via nanoimprint according to a first embodiment of the present invention.

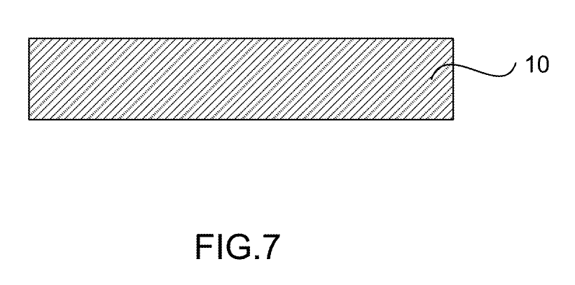

Referring to FIGS. 6 and 7, at S10, a light-emitting element 10 is provided.

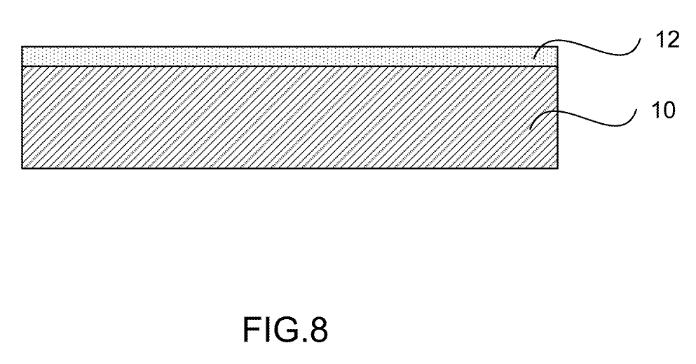

Referring to FIGS. 6 and 8, at S12, precursor is spin coated on the light-emitting element 10 to form a precursor layer 12. The precursor is a sol-gel material or spin-on glass (“SOG”). The sol-gel material or SOG is a viscous liquid at room temperature. After curing, the sol-gel material or SOG can exhibit a demanding dielectric constant, a good thermal stability and a low leakage current, and can be made in a simple process. Therefore, the sol-gel material or SOG gets more and more popular. The SOG is made of SiO₂, TiO₂, ZnO, In₂O₃ or any other material that can be spin coated.

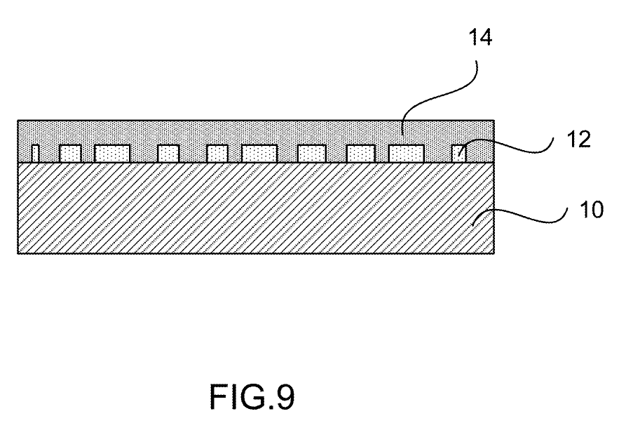

Referring to FIGS. 6 and 9, at S14, a pattern is transferred onto the precursor layer 12 via nanoimprint. The pattern is duplicated on the precursor layer 12 by pressing a mold 14 onto the precursor layer 12. The mold 14 is made of metal, semiconductor, ceramics or plastics for example. Alternatively, the mold 14 can be made of a sol-gel material or SOG according to the method of the present invention.

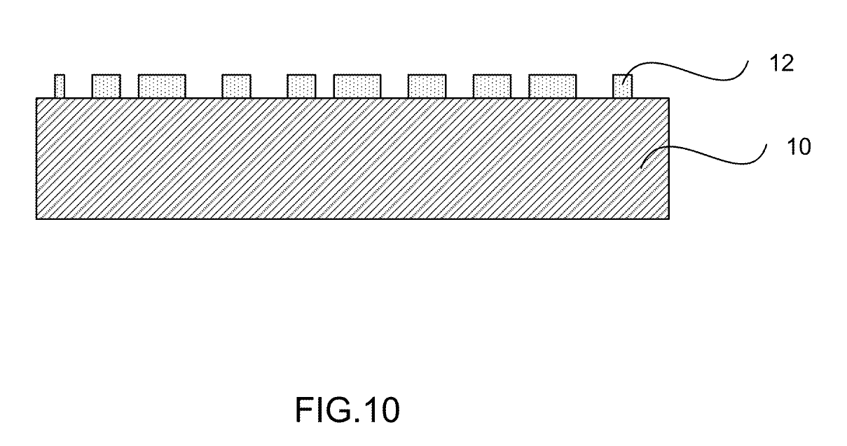

Referring to FIGS. 6 and 10, at S16, the precursor layer 12 is cured. The precursor layer 12 carries the pattern in a textured structure. The textured structure includes photonic crystals arranged in a two-dimensional manner. The photonic crystals can be used in a light-emitting diode (“LED”) to enhance the light-extraction efficiency of the LED or modify the lighting profile of the LED. The textured structure includes triangular, square and/or hexagonal lattices.

The light-emitting element 10 is an LED in the first embodiment. The method according to the invention can however be used to make other semiconductor products such as liquid crystal display panels, solar cells and wafers.

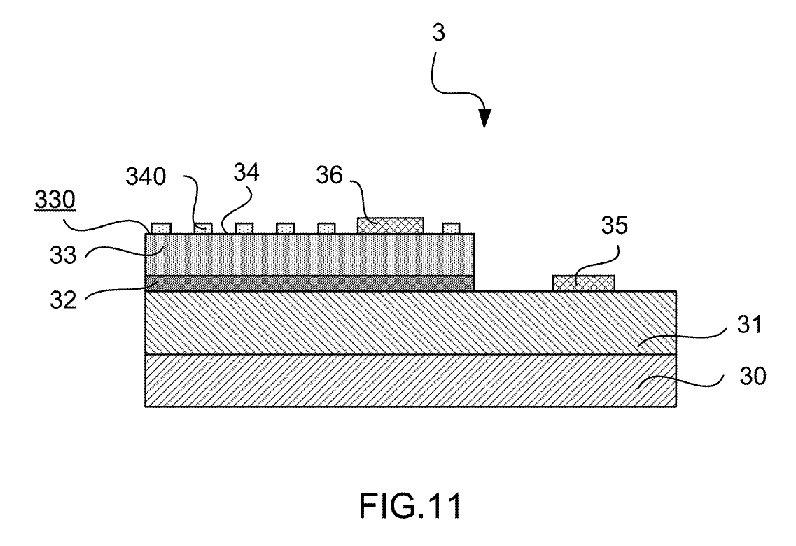

Referring to FIG. 11, a light-emitting device 3 includes a substrate 30, a first semiconductor layer 31, a light-emitting layer 32, a second semiconductor layer 33, a precursor layer 34, a first electrode 35 and a second electrode 36. The first semiconductor 31 is provided on the substrate 30. The first semiconductor layer 31 is an n-typed dosed semiconductor layer. The light-emitting layer 32 is provided on the first semiconductor layer 31. The second semiconductor layer 33 is provided on the light-emitting layer 32, and is made with a surface 330. The second semiconductor layer 33 is a p-type dosed semiconductor layer. The precursor layer 34 is provided on the surface 330, and made with a thin-film structure 340. The first electrode 35 is connected to the first semiconductor layer 31 while the second electrode 36 is connected to the second semiconductor layer 33.

In practice, the material of the first semiconductor layer 31 and that of the second semiconductor layer 33 can be exchanged. That is, the first semiconductor layer 31 can be a p-type dosed semiconductor layer while the second semiconductor layer 33 can be an n-typed dosed semiconductor layer.

The first semiconductor layer 31 and the second semiconductor layer 33 often exhibit extremely high refractive indexes. Therefore, total reflection often occurs on the surface and at the interface, and causes loss of light. For example, the refractive index of GaP is 3.5, and only 19% of the light emitted from a light-emitting device including semiconductor layers made of GaP can be extracted because of the total reflection on the surface and at the interface.

To increase the light-extraction rate, the precursor 34 is made with the textured structure 340 to increase the transmittance of the light-emitting device 3. The textured structure 340 is made on the precursor layer 34 by nanoimprint. At first, precursor is coated on the second semiconductor layer 33 to form the precursor layer 34. Then, a mold is pressed on the precursor layer 34, thus transferring a pattern onto the precursor layer 34 from the mold. Finally, the precursor layer 34 is cured to form the textured structure 340.

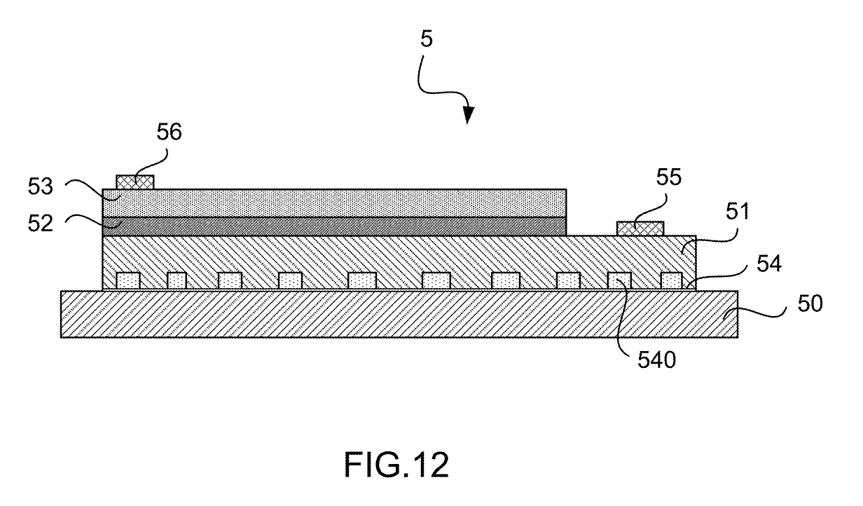

Referring to FIG. 12, a light-emitting device 5 includes a substrate 50, a precursor layer 54, a first semiconductor layer 51, a light-emitting layer 52, a second semiconductor layer 53, a first electrode 55 and a second electrode 56. The precursor layer 54 is sandwiched between the substrate 50 and the first semiconductor layer 51. The light-emitting device 5 casts light downward. The substrate 50 is a transparent substrate. The precursor layer 54 is made with a textured structure to increase the transmittance of the light-emitting device 5.

As mentioned above, in a method for making a thin-film structure via nanoimprint according to the present invention, a sol-gel material or SOG is used as precursor and nanoimprint is used to make a textured structure of an LED with a high light-extraction rate. The method of the present invention is simpler than the photolithography addressed in the Conventional methods that includes the steps of coating a photo-resist layer, baking, exposure, development and etc.

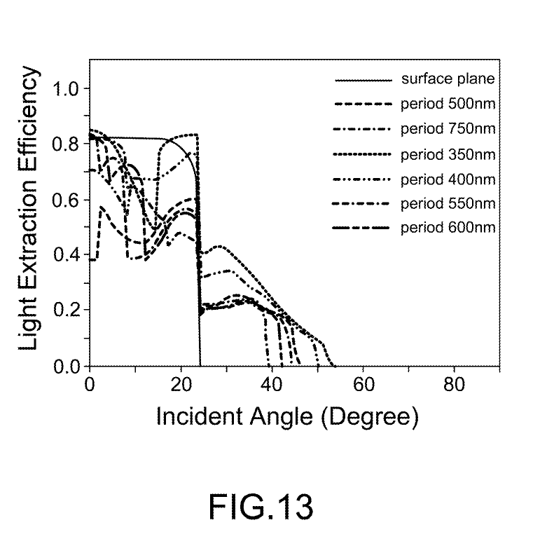

Referring to FIG. 13, made by far-field profile based on electromagnetic theorem, there are shown light-extraction rates of the light-emitting devices of the present invention versus incident angles. By changing the period and depth of the textured structure, light can still be transmitted through the semiconductors to increase the light-extraction rates by up to 18% even when the incident angles reach 23.6°.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A method for making a thin-film structure of a light-emitting device via nanoimprint including the steps of:
providing a light-emitting element 10;
providing a film 12 on the light-emitting element 10 via spin coating precursor on the light-emitting element 10;
forming a pattern on the film 12 by nanoimprint; and
curing the film 12, thus transforming the precursor to the thin-film structure.

2. The method according to claim 1, wherein the light-emitting element 10 is a light-emitting diode.

3. The method according to claim 1, wherein the thin-film structure is a textured structure.

4. The method according to claim 3, wherein the textured structure includes photonic crystals arranged in a two-dimensional manner.

5. The method according to claim 4, wherein the textured structure includes at least one lattice selected from the group consisting of triangular lattices, square lattices and hexagonal lattices.

6. The method according to claim 1, wherein the precursor is a sol-gel material.

7. The method according to claim 1, wherein the precursor is spin-on glass.

8. The method according to claim 7, wherein the spin-on glass is made of a material selected from the group consisting of SiO₂, TiO₂, ZnO and In₂O₃.

9. The method according to claim 1, wherein the step of forming a pattern on the film 12 by nanoimprint includes the step of pressing a mold on the film 12.

10. A light-emitting device including:
a substrate 30;
a first semiconductor layer 31 formed on the substrate 30;
a light-emitting layer 32 formed on the first semiconductor layer 31;
a second semiconductor 33 formed on the light-emitting layer 32;
a precursor layer 34 formed on the second semiconductor 33 so that the precursor layer 34 includes a thin-film structure 340;
a first electrode 35 connected to the first semiconductor layer 31; and
a second electrode 36 connected to the second semiconductor layer 33.

11. The light-emitting device according to claim 10, wherein the thin-film structure 340 is formed on the precursor layer 34 via nanoimprint.

12. The light-emitting device according to claim 10, wherein the thin-film structure is a textured structure.

13. The light-emitting device according to claim 12, wherein the textured structure includes photonic crystals arranged in a two-dimensional manner.

14. The light-emitting device according to claim 13, wherein the textured structure includes at least one lattice selected from the group consisting of triangular lattices, square lattices and hexagonal lattices.

15. The light-emitting device according to claim 10, wherein the precursor is a sol-gel material.

16. The light-emitting device according to claim 10, wherein the precursor is spin-on glass.

17. The light-emitting device according to claim 16, wherein the spin-on glass is made of a material selected from the group consisting of SiO₂, TiO₂, ZnO and In₂O₃.

18. The light-emitting device according to claim 10, wherein the first semiconductor layer 35 is selected from the group consisting of a n-type dosed semiconductor layer and a p-type dosed semiconductor layer.

19. The light-emitting device according to claim 10, wherein the second semiconductor layer 36 is selected from the group consisting of a n-type dosed semiconductor layer and a p-type dosed semiconductor layer.
